(19) United States
(12) Patent Application Publication
(10) Pub. No.: US 2004/0180544 A1
(43) Pub. Date: Sep. 16, 2004

(54) Silicon substrate etching method and etching apparatus

(75) Inventors: Kazuo Kasai, Amagasaki-shi (JP); Yoshiyuki Nozawa, Amagasaki-shi (JP); Hiroaki Kouno, Amagasaki-shi (JP)

Correspondence Address: DARBY & DARBY P.C., P. O. BOX 5257, NEW YORK, NY, 10150-5257, US

(73) Assignee: Sumitomo Precision Products Co., Ltd., Amagasaki-shi (JP)

(21) Appl. No.: 10/812,747

(22) Filed: Mar. 29, 2004

Related U.S. Application Data
(63) Continuation of application No. PCT/JP02/09734, filed on Sep. 20, 2002.

(30) Foreign Application Priority Data
Sep. 28, 2001 (JP) 2001-299435

(51) Int. Cl. H01L 21/302; H01L 21/461

(52) U.S. Cl. 438/689; 438/691

(57) ABSTRACT

The present invention relates to a method and device for etching a silicon substrate that can keep surface unevenness of a structured surface formed by etching to within a fixed value. After an etching mask is formed on its surface, a silicon substrate S is mounted on a base 3 in an etching device 1. An etching gas (SF6) and a protective film forming gas (C4F8) are supplied to a chamber 2. The SF6 gas and the C4F8 gas supplied to the chamber are converted to plasma using a coil 16 to which high-frequency electrical power is applied. For example, by supplying a large amount of SF6 gas while high-frequency electrical power is applied to the base 3, dry etching primarily at the etching grounds is advanced. Conversely, by supplying a large amount of C4F8 gas, protective film formation primarily to the etching structured surfaces is advanced. By repeating these steps, deep grooves with smooth structured surfaces can be formed.

### CROSS-REFERENCE TO RELATED APPLICATION

This application is a Continuation of International Patent Application Serial No. PCT/JP02/09734 filed Sep. 20, 2002, which was published in Japanese on Apr. 10, 2003 as WO 03/030239 A1, and which is incorporated herein by reference in its entirety.

### BACKGROUND OF THE INVENTION

The present invention relates to a silicon substrate etching method and device for the same forming a surface structure, e.g., a groove, on a silicon substrate using a dry etching process.

In fields such as the semiconductor IC field where structures such as grooves are formed on silicon substrates using a dry etching process, higher-level integration and higher densities are being achieved, creating a demand for an etching technology that can form trenches (deep grooves or holes) with high precision. An example of a conventional etching method for trench etching is described in PC (WO) 7-503815.

In this etching method, an etching mask is formed on the silicon substrate surface in a desired shape, and a mixed gas of SF6 and Ar formed as plasma is used to dry etch the substrate surface to form the groove or hole. Then, in a polymerization step, a protective film is formed on the side walls of the groove or hole (hereinafter referred to as groove or the like) using a mixed gas of CHF3 and Ar formed as a plasma. This etching step and this polymerization step are alternated to form a deep groove or a deep hole (hereinafter referred to as deep groove or the like).

With this etching method, the walls of the successively dry etched groove or the like is covered with a protective film after each etching, thus allowing the protective film to protect the side walls during the next dry etching. This prevents extreme side etching and undercutting, making it possible to form a groove or the like formed with apparently vertical wall surfaces.

This conventional etching method, however, has the problems described below.

In this conventional etching method, an etching step not accompanied by the formation of a protective film on the wall surfaces is repeated, alternated with a step for forming a protective film on the wall surface. In the etching step, the silicon substrate surface is etched, with the newly formed wall surface resulting from the progression of etching not being protected by a protective film. Thus, in the etching step, the wall surface is etched along with the etching ground (the bottom surface of the groove or the like). As a result, the wall surface 101 of the groove 100 forms a wave-like surface vertically, reducing the processing precision. This unevenness on the wall surface 101 becomes a hindrance to increasing the level of integration and density in semiconductor integrated circuits.

When the deep groove 100 described above is to be used to form a trench capacitor 102 as shown in FIG. 6, the unevenness of the wall surface 101 creates thick and thin areas on an insulating layer 103. This results in fractures having a tendency to form in the thin areas, thus reducing insulative properties. In the figure, there is shown a silicon substrate S, and an electrode 104 formed from polysilicon.

The dry etching process described above is also used in production of micro-machines. If this conventional etching method is used, for example, to form a gear, there will be significant unevenness on the teeth surface, leading to friction drag and power transfer loss.

### SUMMARY OF THE INVENTION

The object of the present invention is to overcome these problems and to provide a silicon substrate etching method and device for the same capable of keeping unevenness of a structure surface formed by a dry etching process at no more than a predetermined value.

In order to achieve the objects described above, the present invention provides a method for etching a silicon substrate including a mask-forming step for forming an etching mask on a silicon substrate surface and an etching step for forming a predetermined structured surface by dry etching the silicon substrate surface. The etching step is implemented by repeating, in sequence: a step for primarily advancing the dry etching at an etching ground using etching gas and a protective film forming gas; a step for forming a protective film using the protective film forming gas on a structured surface formed by the dry etching; and a step for removing the protective film formed on the etching ground.

With this etching method, in the step for primarily advancing dry etching at the etching ground, the etching ground is etched by the etching gas while the structured surface perpendicular to the etching ground formed progressively by etching is immediately covered by a protective film resulting from the protective film forming gas. In the subsequent protective film forming step, the perpendicular structured surface is further covered by protective film.

Thus, with this etching method, the perpendicular structured surface formed progressively through etching can be immediately covered by protective film while further covering is provided in the subsequent step. As a result, side etching and undercutting, described above, can be reliably prevented, making it possible to keep unevenness of the perpendicular structured surface to no more than 200 nm.

The etching gas can be SF6 or the like and the protective film forming gas can be a fluorocarbon gas (CxFy) such as C4F8.

In the etching method described above, it is possible to have a small amount of the protective film forming gas supplied during the step for primarily advancing dry etching and a large amount of the protective film forming gas supplied in the protective film forming step. This makes it possible to increase the etching speed during the step for advancing dry etching while allowing a strong protective film to be formed during the protective film forming step.

According to another aspect, a bias voltage can be provided by applying electrical power to the silicon substrate during the step for primarily advancing dry etching and the protective film removal step or the protective film removal step. This makes it possible to physically etch the etching ground with ion irradiation. As a result, etching speed is increased during the step for advancing dry etching while the protective film formed on the etching ground can be easily removed during the step for removing the protective film. This reduces overall etching processing time. Also, a smooth transition is made possible from the protective film removal step and the dry etching advancement step, allowing these steps to be performed as if they were a single step.

According to another aspect, the present invention provides a method for etching a silicon substrate wherein the following steps are repeatedly performed in sequence: a mask forming step for forming an etching mask on a silicon substrate surface; and an etching step for forming a predetermined structured surface by dry etching the silicon substrate surface through an opening in the etching mask using an etching gas converted to plasma via high-frequency electrical power.

The etching step is performed by repeatedly performing, in sequence: a step for primarily advancing dry etching of an etching ground using an etching gas and a protective film forming gas; and a step for primarily forming a protective film primarily on a structured surface perpendicular to the etching ground using an etching gas and a protective film forming gas.

With this etching method, the etching ground is etched by the etching gas during the step primarily for advancing dry etching at the etching ground while the structured surface perpendicular to the etching ground formed progressively by etching is immediately covered by protective film formed by the protective film forming gas. The subsequent protective film forming step further covers the perpendicular structured surface with protective film. As a result, side etching and undercutting can be reliably prevented and unevenness in the perpendicular structured surface can be kept to no more than 200 nm.

According to another aspect, in this etching method, a large amount of etching gas and a small amount of the protective film forming gas is supplied during the step for primarily advancing dry etching and a small mount of etching gas and a large amount of protective film forming gas is supplied in the step primarily for forming protective film. This increases the etching speed in the dry etching advancement step while providing a firm protective film on the perpendicular structured surface in the protective film forming step.

According to another aspect, a bias potential is provided by continuously applying electrical power to the silicon substrate during the etching step. This allows physical etching by ion irradiation on the etching ground so that etching speed can be increased in the dry etching advancement step while actively preventing formation of protective film on the etching ground during the protective film forming step. As a result, the overall etching processing time can be reduced.

According to another aspect, the present invention provides a method for etching a silicon substrate wherein the following steps are repeatedly performed in sequence: a mask forming step for forming an etching mask on a silicon substrate surface; and an etching step for forming a predetermined structured surface by dry etching the silicon substrate surface through an opening in the etching mask using an etching gas converted to plasma via high-frequency electrical power.

The etching step is performed by repeatedly performing, in sequence: a step for providing a bias voltage by continuously applying electrical power to the silicon substrate during the etching step, a step for primarily advancing dry etching of an etching ground using an etching gas and a protective film forming gas; and a step for primarily forming a protective film primarily on a structured surface perpendicular to the etching ground using an etching gas and a protective film forming gas.

With this method, in the step for primarily advancing dry etching of the etching ground, the etching ground is etched with etching gas and ion irradiation. The structured surface perpendicular to the etching ground progressively formed by etching is immediately covered by protective film formed by the protective film forming gas and is further covered by protective film during the subsequent protective film forming step. As a result, side etching and undercutting can be reliably prevented and the unevenness of the perpendicular structured surface can be kept to no more than 200 nm.

According to another aspect, a small amount of the protective film forming gas is supplied during the step for primarily advancing dry etching and a large amount of the protective film forming gas is supplied in the step primarily for forming protective film. This increases the etching speed in the dry etching advancement step and provides stronger protective film formation during the protective film formation step.

According to another aspect, electrical power applied to the silicon substrate is set high during the step for primarily advancing dry etching and is set low during the step for primarily advancing protective film formation. This increases the iron irradiation rate during the dry etching advancement step and increases etching speed. In the protective film formation step, the removal of protective film formed on the perpendicular structured surface due to diagonal irradiation ions is minimized. This provides a firm protective film.

According to another aspect, a reactive gas is used for the etching gas. This allows the silicon substrate to be etched with an improved etching speed. The reactive etching gas can be SF6 or the like.

According to another aspect, an etching gas and a protective film forming gas converted to plasma are used; and the high-frequency electrical power used when generating plasma is set high during the step for primarily advancing dry etching and set low during the step for primarily forming protective film.

In this etching step, the dry etching advancement step can be performed first followed by repeated execution of the steps, or the protective film formation step can be performed first followed by repeated execution of the steps. However, in order to reduce unevenness, starting with the protective film formation step is preferred.

The etching methods described above can be suitably implemented in the following etching devices.

According to one aspect, a device for etching a silicon substrate includes: an etching chamber housing a silicon substrate serving as an item to be etched; a base disposed below the etching chamber and on which the silicon substrate is mounted; means for supplying etching gas supplying etching gas in the etching chamber; means for supplying protective film forming gas supplying protective film forming gas in the etching chamber; means for reducing pressure reducing pressure in the etching chamber; means for generating plasma, including a coil disposed at an outer perimeter of the etching chamber and opposing the etching chamber, wherein high-frequency electrical power is applied to the coil and etching gas and protective film forming gas supplied to the etching chamber are converted to plasma; means for applying base power applying high-frequency electrical power to the base; means for controlling gas flow controlling the etching gas and the protective film forming gas supplied to the etching chamber via the etching gas supplying means and the protective film forming gas supplying means; means for controlling coil power controlling electrical power applied to the coil in the plasma generating means; and means for controlling base power controlling electrical power applied to the base by the base power applying means. The gas flow controlling means is formed so that the protective film forming gas is continuously supplied to the etching chamber and the etching gas is intermittently supplied to the etching gas.

According to another aspect, the gas flow controlling means supplies a large amount of the protective film forming gas to the etching chamber when the etching gas is not being supplied and a small amount of the protective film forming gas to the etching chamber when the etching gas is being supplied.

According to another aspect, an etching device includes: an etching chamber housing a silicon substrate serving as an item to be etched; a base disposed below the etching chamber and on which the silicon substrate is mounted; means for supplying etching gas supplying etching gas in the etching chamber; means for supplying protective film forming gas supplying protective film forming gas in the etching chamber; means for reducing pressure reducing pressure in the etching chamber; means for generating plasma, including a coil disposed at an outer perimeter of the etching chamber and opposing the etching chamber, wherein high-frequency electrical power is applied to the coil and etching gas and protective film forming gas supplied to the etching chamber are converted to plasma; means for applying base power applying high-frequency electrical power to the base; means for controlling gas flow controlling flows of the etching gas and the protective film forming gas supplied to the etching chamber via the etching gas supplying means and the protective film forming gas supplying means; means for controlling coil power controlling electrical power applied to the coil in the plasma generating means; and means for controlling base power controlling electrical power applied to the base by the base power applying means. The gas flow controlling means is formed so that the etching gas and the protective film forming gas are continuously supplied to the etching chamber while flows thereof are periodically changed, with the flows being controlled so that phases thereof are opposite of each other.

According to another aspect, an etching device includes: an etching chamber housing a silicon substrate serving as an item to be etched; a base disposed below the etching chamber and on which the silicon substrate is mounted; means for supplying etching gas supplying etching gas in the etching chamber; means for supplying protective film forming gas supplying protective film forming gas in the etching chamber; means for reducing pressure reducing pressure in the etching chamber; means for generating plasma, including a coil disposed at an outer perimeter of the etching chamber and opposing the etching chamber, wherein high-frequency electrical power is applied to the coil and etching gas and protective film forming gas supplied to the etching chamber are converted to plasma; means for applying base power applying high-frequency electrical power to the base; means for controlling gas flow controlling flows of the etching gas and the protective film forming gas supplied to the etching chamber via the etching gas supplying means and the protective film forming gas supplying means; means for controlling coil power controlling electrical power applied to the coil in the plasma generating means; and means for controlling base power controlling electrical power applied to the base by the base power applying means. The base power controlling means is formed so that the electrical power applied to the base is periodically changed.

According to another aspect, the base power controlling means periodically changes the electrical power applied to the base, applying low electrical power to the base when the etching gas is not being supplied and applying high electrical power when the etching gas is being supplied. Furthermore, means for controlling coil power can periodically change the electrical power applied to the coil.

According to another aspect, an etching device includes: an etching chamber housing a silicon substrate serving as an item to be etched; a base disposed below the etching chamber and on which the silicon substrate is mounted; means for supplying etching gas supplying etching gas in the etching chamber; means for supplying protective film forming gas supplying protective film forming gas in the etching chamber; means for reducing pressure in the etching chamber; means for generating plasma, including a coil disposed at an outer perimeter of the etching chamber and opposing the etching chamber, wherein high-frequency electrical power is applied to the coil and etching gas and protective film forming gas supplied to the etching chamber are converted to plasma; means for applying high-frequency electrical base power to the base; means for controlling flows of the etching gas and the protective film forming gas supplied to the etching chamber via the etching gas supplying means and the protective film forming gas supplying means; means for controlling electrical coil power applied to the coil in the plasma generating means; and means for controlling electrical base power applied to the base by the base power applying means. The coil power controlling means is formed so that electrical power applied to the coil is periodically changed.

According to another aspect, coil power controlling means periodically changes power applied to the coil, applying low electrical power when the etching gas is not being supplied and applying high electrical power when the etching gas is being supplied.

According to another aspect, base power controlling means periodically changes electrical power applied to the base, applying low electrical power when a small amount of the etching gas is being supplied and applying high electrical power to the base when a large amount of the etching gas is being supplied. Coil power controlling means can periodically change electrical power applied to the coil, applying low electrical power when a small amount of the etching gas is being supplied and applying a high electrical power when a large amount of the etching gas is being supplied.

### BRIEF DESCRIPTION OF THE DRAWINGS

FIG. 1 is a partial block diagram illustrating the overall structure of an etching device preferable for the present invention.

FIG. 2 (a) is a timing chart showing the control status of SF6 gas flow. FIG. 2 (b) is a timing chart showing the control status of C4F8 gas flow. FIG. 2 (c) is a timing chart showing the control status of high-frequency power applied to a coil. FIG. 2 (d) is a timing chart showing the control status of high-frequency power applied to a base.

FIG. 3 is a drawing illustrating the evaluation method for an embodiment.

FIG. 4 is a drawing showing the evaluation results for an embodiment.

FIG. 5 is a cross-section drawing showing a deep groove formed in a silicon substrate using a conventional etching method.

FIG. 6 is a cross-section drawing showing a trench capacitor formed using a deep groove formed by a conventional etching method.

### DETAILED DESCRIPTION OF THE PREFERRED EMBODIMENTS

The present invention will be described in further detail, with references to the attached drawings.

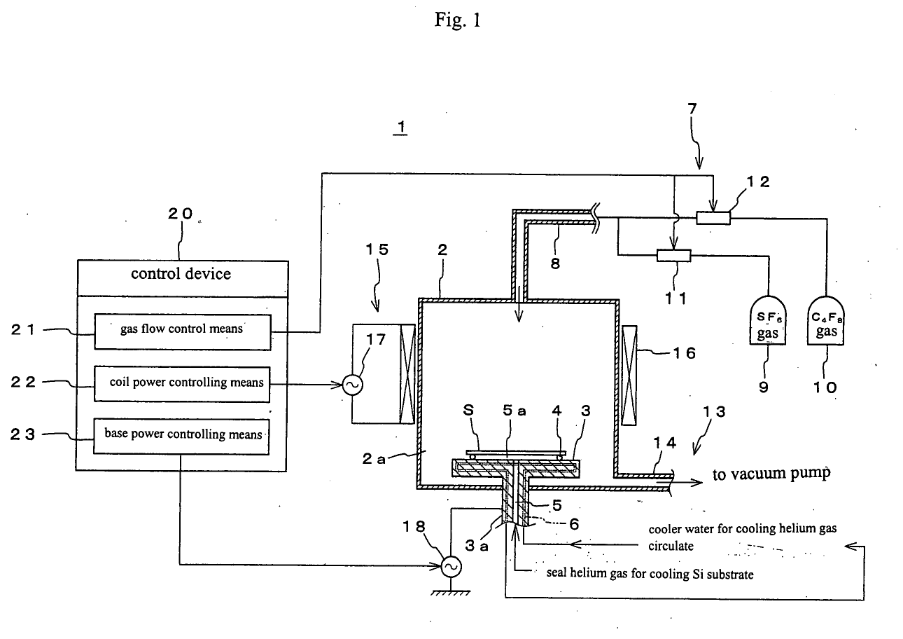

First, the structure of an etching device according to an embodiment will be described, with references to FIG. 1. FIG. 1 is a cross-section drawing with a block diagram section providing a simplified illustration of the structure of the etching device according to this embodiment.

As shown in FIG. 1, an etching device 1 is formed from ceramic and is equipped with: a case-shaped etching chamber 2 within which is formed an etching chamber 2a; a base 3 disposed below the etching chamber 2a and on which is mounted the silicon substrate S to be etched; a gas supply unit 7 supplying the etching gas and the protective film forming gas into the etching chamber 2a; a decompression unit 13 decompressing the etching chamber 2a; a plasma generating unit 15 forming plasma from the etching gas and the protective film forming gas supplied to the etching chamber 2a; a high-frequency power supply 18 providing high-frequency power to the base 3; and a control device 20 controlling the actions of these units.

The silicon substrate S is mounted on the base 3, interposed by a sealing member such as an O-ring 4. The base 3 is disposed so that a base section 3a thereof is extended outside the etching chamber 2a. At the center is a communicating path 5 communicating with a space 5a formed between the base 3 and the silicon substrate S. Helium gas fills and is sealed in this space 5a by way of this communicating path 5. Also, a cooling-water circulation path 6 is formed in the base 3. Cooling water (20 deg C.) circulating through the cooling-water circulation path 6 cools the silicon substrate S by way of the base 3 and the helium gas. The high-frequency power supply 18 applies high-frequency power at 13.56 MHz to the base 3, generating a bias potential at the base 3 and the silicon substrate S mounted on the base 3.

The gas supply unit 7 is formed from a gas supply tube 8 connected to the upper end of the etching chamber 2 and gas cylinders 9, 10 connected to the gas supply tube 8 by way of mass-flow controllers 11, 12 respectively. The mass-flow controllers 11, 12 adjust the flow from the gas cylinders 9, 10 to the etching chamber 2a. The gas cylinder 9 is filled with SF6 gas for etching, and the gas cylinder 10 is filled with C4F8 gas for protective film formation.

The decompression unit 13 is formed from an exhaust pipe 14 and a vacuum pump, not shown in the figure, connected to the exhaust pipe 14. This vacuum pipe (not shown) decompresses the inside of the etching chamber 2a to a predetermined low pressure (e.g., 1.33 Pa).

The plasma generating unit 15 is formed from a coil 16 extending along the outer perimeter of the etching chamber 2 at a position higher than the base 3, and a high-frequency power supply 17 applying high-frequency power of 13.56 MHz to the coil 16. Supplying the coil 16 with high-frequency power results in the formation of a fluctuating magnetic field. Gas supplied to the etching chamber 2a is turned into a plasma by the electric field induced by this fluctuating magnetic field.

The control device 20 is formed from: gas flow-control means 21 controlling the mass-flow controllers 11, 12 to adjust the flow of gas supplied by the gas cylinders 9, 10 to the etching chamber 2a; coil power controlling means 22 controlling the high-frequency power applied to the coil 16; and base power controlling means 23 controlling the high-frequency power applied to the base 3.

Next, the etching of the silicon substrate S by the etching device 1 presented above will be described.

First, photolithography or the like is used to form an etching mask (e.g., a resist film, SiO2 film, or the like) in the desired shape on the silicon substrate S. Then, the silicon substrate S is sent into the etching chamber 2 and mounted on the base 3 by way of the O-ring 4. Then, helium gas from the communicating path 5 fills the space 5a. Cooling water continuously circulates through the cooling-water circulation path 6.

Next, SF6 gas and C4F8 gas are sent from the gas cylinder 9 and the gas cylinder 10 respectively into the etching chamber 2a. High-frequency power is sent to the coil 16 and high-frequency power is sent to the base 3.

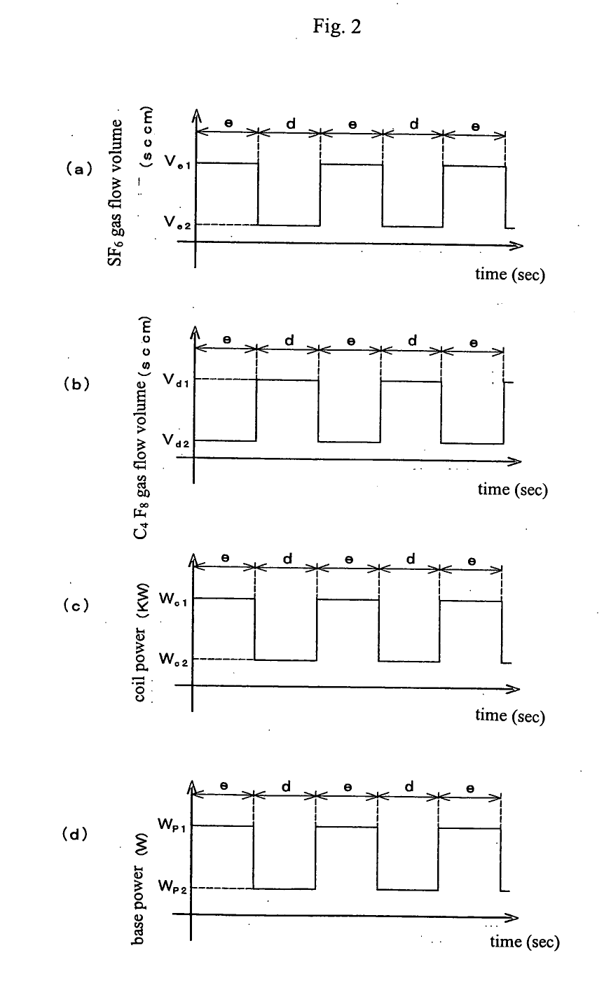

Gas flow controlling means 21 controls the flow of the SF6 gas and the C4F8 gas in the following manner. As shown in FIG. 2 (a), the flow of the SF6 gas into the etching chamber 2a changes as a rectangular waveform from Ve2 to Ve1. The flow of the C4F8 gas changes as a rectangular waveform from Vd2 to Vd1.

Coil power controlling means 22 and base power controlling means 23: change the high-frequency power applied to the coil 16 to a rectangular waveform varying between Wc2 and Wc1, as shown in FIG. 2 (c); change the high-frequency power applied to the base 3 to a rectangular waveform varying between Wp2 and Wp1; and provide control so that the phase of the high-frequency power applied to the coil 16 and the phase of the high-frequency power applied to the base 3 are the same.

The SF6 gas and the C4F8 gas supplied to the etching chamber 2a are converted to plasma containing ions, electrons, F radicals, and the like in the changing magnetic field generated by the coil 16. The changing magnetic field maintains the plasma at a high density. The F radicals in the plasma react chemically with Si, taking away Si from the silicon substrate S, i.e., etching is performed on the silicon substrate S. The self-bias potential generated on the silicon substrate S and the base 3 cause ions to accelerate toward the base 3 and the silicon substrate S, leading to collision with the silicon substrate S and resulting in etching. After an interval, these F radicals and ions etch the surface of the silicon substrate S (etching ground) at the mask openings, forming grooves and the like at predetermined widths and depths.

Meanwhile, the plasma conversion of the C4F8 gas results in a polymer that is deposited on the wall surfaces and bottom surfaces (etching ground) of the grooves and the like, resulting in a fluorocarbon film. This fluorocarbon film does not react with F radicals and acts as a protective film against F radicals. This protective film prevents side etching and undercutting.

Thus, in the presence of plasma obtained from SF6 gas and C4F8 gas supplied simultaneously to the etching chamber 2a, etching is performed through F radical and ion irradiation while at the same time an opposing process is taking place in the form of the formation of a protective film on the wall surfaces and bottom surfaces of the grooves and the like by polymerization. More specifically, the bottom surfaces receive more ion irradiation so that polymer removal through ion irradiation is more pronounced than polymer deposition, thus making F-radical and ion-etching proceed quicker. At the wall surfaces, which receive less ion irradiation, the deposition of polymer is more pronounced than the removal of the polymer by ion irradiation, thus making the formation of the protective film proceed quicker.

Taking these issues into account, this embodiment controls the flow of SF6 gas and C4F8 gas, the high-frequency power applied to the coil 16, and the high-frequency power applied to the base 3 in the manner described above and shown in FIG. 2.

More specifically, in an interval e shown in FIG. 2, the flow of SF6 gas is Ve1, which is high, while the flow of C4F8 gas is Vd2, which is low, and the high-frequency power applied to the coil 16 is Wc1, which is high, while the high-frequency power applied to the base 3 is Wp1, which is high. By having a high flow of SF6 gas, a low flow of C4F8 gas, and a high value of high-frequency power applied to the coil 16, F radicals and ions needed for etching can be generated in suitable quantities while polymer formation can be kept to the minimum needed for preventing side etching and undercutting. Also, by keeping the value of the high-frequency power applied to the base 3 high, the ion irradiation speed can be increased, thus increasing the etching speed.

Based on the above, at the etching ground (bottom surfaces) receiving high ion irradiation, the removal of polymer due to ion irradiation is more pronounced than the deposition of polymer so that F-radicals and ions proceed with etching. On the wall surfaces, which receive less ion irradiation, the deposition of polymer is more pronounced than the polymer removal caused by ion irradiation, thus allowing formation of the protective film to proceed. The wall surfaces formed progressively by etching are immediately covered by this protective film.

In an interval d shown in FIG. 2, the flow of SF6 gas is Ve2, which is low, while the flow of C4F8 gas is Vd1, which is high, and the high-frequency power applied to the coil 16 is Wc2, which is low, while the high-frequency power applied to the base 3 is Wp2, which is low. By having a low flow of SF6 gas and a high flow of C4F8 gas, more polymer needed to form the protective film can be generated while the generation of F radicals and ions can be kept to the minimum needed to etch the polymer deposited on the etching ground. Also, by lowering the high-frequency power applied to the base 3, the ion irradiation needed to etch the polymer deposited on the etching ground can take place slower, and the removal of the protective film deposited on the wall surfaces by ion irradiation can be prevented.

Based on the above, at the etching ground (bottom surface), etching is limited to what is needed to remove deposited polymer through ion irradiation. At the wall surfaces, where there is less ion irradiation, more polymer is deposited, forming a strong protective film.

By repeating the e step and the d step described above, a step that primarily involves etching and a step that primarily involves forming protective film can be repeated in an alternating manner so that the wall surfaces progressively formed by etching can be immediately covered by protective film, with the protective film being further strengthened in the next step. As a result, side etching and undercutting can be reliably prevented. Thus, trenches with cavities no more than 200 nm and with vertical inner wall surfaces can be formed in an efficient manner on the silicon substrate S.

In order to provide these characteristics, it would be preferable for the flow Ve1 of the SF6 gas described above to be in the range 60-300 ml/min and the flow Ve2 to be in the range of 0-80 ml/min. The range for the flow Ve2 includes 0 ml/min because, since ions are generated even with C4F8 gas converted to plasma, it is possible that the ions needed to remove polymer deposited on the etching ground can be adequately provided by the C4F8 gas. Also, it would be preferable for the C4F8 gas flow Vd1 to be in the range of 50-260 m/min and the flow Vd2 to be in the range 50-150 m/min.

Also, it would be preferable for the high-frequency power Wc1 applied to the coil 16 to be in the range 800-3000 W and for Wc2 to be in the range 600-2500 W. Furthermore, it would be preferable for the high-frequency power Wp1 applied to the base 3 to be in the range 3-50 W, and for Wp2 to be in the range 0-15 W. The Wp2 range includes 0 W because setting Wp2 to 0 W does not result in removal of deposited polymer on the etching ground in the d step but the polymer is removed in the subsequent e step by ion irradiation. However, since the polymer deposited on the etching ground must be removed in the e step, the overall processing time becomes longer.

Also, it would be preferable for the e step time to be in a range of 3-45 seconds, and for the d step time to be in a range of 3-30 seconds.

With this example, the surface offset of the walls of grooves and the like obtained by etching the silicon substrate S can be kept to no more than 200 nm, thus allowing high-level integration and high densities in semiconductor integrated circuits. For trench capacitors, reduction of insulative properties can be prevented. Also, if gears are formed, transfer loss can be minimized.

In this example, C4F8 is supplied to the etching chamber 2a to form protective film during the step for primarily advancing etching. This provides the following advantages. When forming deep grooves and the like using a conventional etching method in which protective film forming gas is not supplied during the etching advancement step, etching speed is reduced when the mask opening width is narrower, resulting in a “micro-loading” effect. Thus, etching speed varies according to the mask opening width. However, by supplying protective film forming gas during the etching advancement step, the etching speed was found to be roughly constant regardless of the mask opening width. According to this example, etching speed drops because deposition and removal of polymer at the etching ground takes place at the same time, and this effect is most pronounced when the mask opening is wider. Thus, it is believed that etching happens uniformly regardless of the mask opening width as a result.

This is especially advantageous when etching SOI (Silicon on insulator) substrates. More specifically, when an SOI substrate is etched with a conventional etching method using an etching mask having different opening widths, etching is faster at the sections with wider opening widths. Thus, the etching ground reaches the SiO2 layer faster than other openings. If this continues, since etching for the other sections has not been completed, F radicals can burst through the protective film because the F radical cannot react with the SiO2 layer, i.e., the etching speed for the SiO2 layer is significantly lower than the etching speed of Si. “Notching”, where the Si near the boundaries between the Si and SiO2 is eaten away, takes place, reducing processing precision. In our example, the etching speed can be kept relatively constant regardless of the mask opening widths, so “notching” and reduction of processing precision can be prevented.

Also, when SF6 gas and C4F8 gas are supplied separately to the etching chamber 2a, impedance adjustment takes a long time because the impedances of the generated plasma vary according to gas and the flow of the gas even if the power supplied to the coil 16 is the same. Thus, supplying stable power is difficult. In our example, SF6 gas and C4F8 gas are supplied to the etching chamber 2a at the same time, so impedance adjustments that lead to drops in supplied power can be performed easily, making it possible to supply stable power.

### Embodiment

After forming a mask (SiO2) with an opening that is 5 microns×300 microns on the silicon substrate, the silicon substrate was etched.

1. Comparative example

(1) A pressure of 3.99 Pa was used inside the etching chamber 2a. (2) SF6 gas was used as the etching gas and C4F8 gas was used as the protective film forming gas. (3) The SF6 gas flow Ve1 was set to 150 m/min, and Vd2 was set to 0 m/min. The high-frequency power Wc1 applied to the coil 16 was set to 2500 W, and Wc2 was set to 1000 W. (6) The high-frequency power Wp1 applied to the base 3 was set to 20 W and Wp2 was set to 0 W. Control was provided as indicated in FIG. 2, and a hole with a depth of 50 microns was formed on the silicon substrate.

2. Embodiment

(1) A pressure of 3.99 Pa was used in the etching chamber 2a. (2) SF6 gas was used as the etching gas, and C4F8 gas was used as the protective film forming gas. (3) The SF6 gas flow Ve1 was set to 260 ml/min, and Ve2 was set to 7 ml/min. (4) The C4F8 gas flow Vd1 was set to 150 ml/min, and Vd2 was set to 13 ml/min. (5) The high-frequency power Wp1 applied to the base 3 was set to 20 W, and Wp2 was set to 5 W. These are controlled as indicated in FIG. 2 and a hole with depth 50 microns was formed on the silicon substrate.

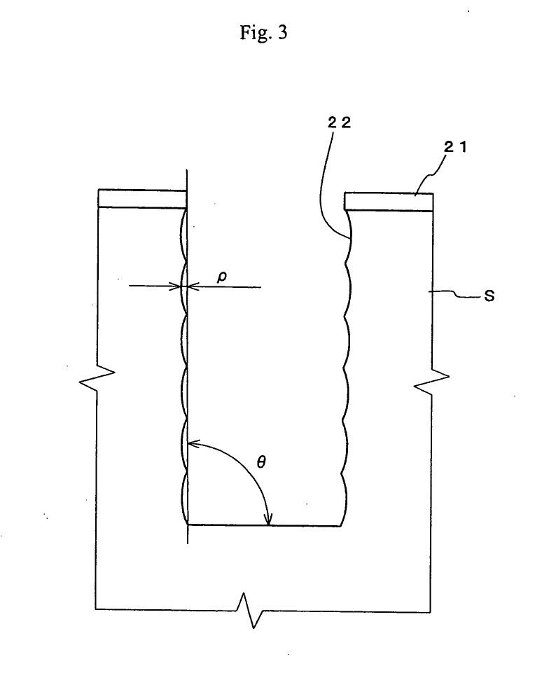

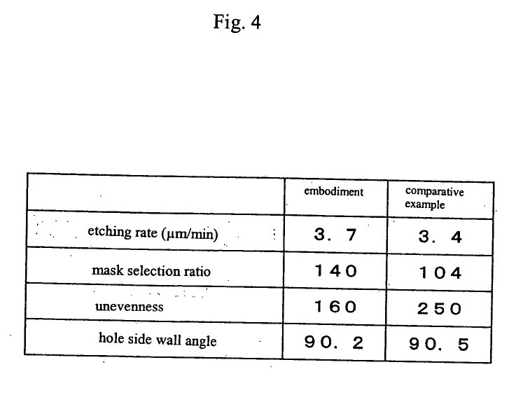

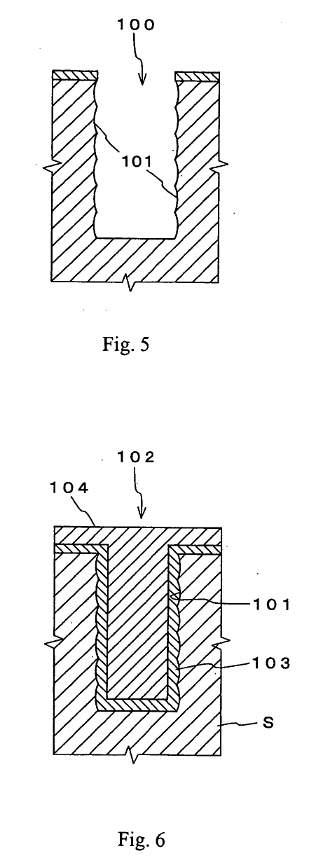

FIG. 4 shows, for the embodiment and the comparative example, the etching rate, the mask selection ratio, and the dimensional characteristics of the hole formed on the silicon substrate by etching. The etching rate is expressed as etching depth per minute, and higher values are preferred. The mask selection ratio is the ratio between the silicon (Si) etching depth and the mask (SiO2) etching depth, i.e., mask selection ratio=Si etching depth/SiO2 etching depth. High values are preferred. The unevenness p (mn), as shown in FIG. 3, expresses the depth of the unevenness formed on the side walls of the hole. Lower values are preferable. The hole side-wall angle θ (deg) expresses the angle relative to the horizontal plane (corresponds to the bottom surface of the silicon substrate). Values close to 90 deg are preferable here. The figure also shows the silicon substrate S, a mask 21, and a hole wall surface 22.

As shown in FIG. 4, the embodiment in which both the SF6 gas (etching gas) and the C4F8 gas (protective film forming gas) are supplied to the etching chamber throughout all the etching steps and the flows are changed periodically so that they are at reverse phase of each other provides a superior etching rate, mask selection ratio, unevenness ρ, and hole side wall angle θ compared to the comparative example in which the SF6 gas (etching gas) and the C4F8 gas (protective film forming gas) are supplied to the etching chamber 2 in an alternating manner.

What is believed to be an optimal embodiment is described above, but of course the present invention is not restricted to this implementation.

As described above, by setting etching conditions such as the flow of SF6 gas and C4F8 gas, the high-frequency power applied to the coil 16, and the high-frequency power applied to the base 3, so that they vary within the ranges described above, it is possible to have primarily an etching step and a protective film formation step performed repeatedly in an alternating manner. Also, a groove or the like with perpendicular wall surfaces and unevenness of no more than 200 nm can be formed on the silicon substrate S. Thus, the objects of the present invention can be achieved by combining the above etching conditions as appropriate.

More specifically, the power applied to the coil 16 and the power applied to the base 3 can be set constant while the flow of SF6 gas and C4F8 gas can be varied over the ranges described above. Alternatively, just the power applied to the coil 16 can be set constant while the power applied to the base 3 and the flow of SF6 gas and C4F8 gas are varied over the ranges described above. Or, conversely, the power applied to the base 3 can be set constant while the power applied to the coil 16 and the flow of SF6 gas and C4F8 gas are varied over the ranges described above.

Also, the flow of SF6 gas and C4F8 gas and the power applied to the coil 16 can be set constant while the power applied to the base 3 is varied over the range described above. Or, the SF6 gas and the C4F8 gas flow can be set constant while the power applied to the coil 16 and the power applied to the base 3 are varied over the range described above.

Also, in this embodiment, the etching step starts from step e, with step e and step d being performed repeatedly. The present invention is not restricted to this, and it would be possible to implement the present invention starting with step d and alternating between step d and step e. This would allow the unevenness in the resulting groove side walls to be further reduced (especially directly below the mask).

As described above, the etching method and etching device of the present invention can be used to form structural surfaces, e.g., grooves, on a silicon substrate.

What is claimed is:

1. A method for etching a silicon substrate, comprising:
forming an etching mask on a silicon substrate surface; and
performing an etching step for forming a predetermined structured surface by dry etching said silicon substrate surface,
wherein said etching step comprises repeating in sequence:
advancing said dry etching primarily at an etching ground using an etching gas and a protective film forming gas;
forming a protective film using said protective film forming gas on a structured surface formed by said dry etching; and
removing said protective film formed on said etching ground.

2. A method for etching a silicon substrate according to claim 1 wherein a small amount of said protective film forming gas is supplied during advancing the dry etching and a large amount of said protective film forming gas is supplied in forming said protective film.

3. A method for etching a silicon substrate according to claim 1, wherein a bias voltage is provided by applying electrical power to said silicon substrate during advancing the dry etching and removing said protective film or during removing said protective film.

4. A method for etching a silicon substrate according to claim 1, wherein a reactive gas is used for said etching gas.

5. A method for etching a silicon substrate, comprising repeating in sequence:
forming an etching mask on a silicon substrate surface; and
performing an etching step for forming a predetermined structured surface by dry etching said silicon substrate surface through an opening in said etching mask using an etching gas converted to plasma via high-frequency electrical power,
wherein said etching step comprises repeating in sequence:
advancing primarily dry etching of an etching ground using an etching gas and a protective film forming gas; and
forming a protective film primarily on a structured surface perpendicular to said etching ground using an etching gas and a protective film forming gas.

6. A method for etching a silicon substrate according to claim 5, wherein a small amount of said protective film forming gas is supplied during advancing the dry etching and a large amount of said protective film forming gas is supplied in forming the protective film.

7. A method for etching a silicon substrate according to claim 5, wherein a bias potential is provided by continuously applying electrical power to said silicon substrate during said etching step.

8. A method for etching a silicon substrate according to claim 7, wherein electrical power applied to said silicon substrate is set high during advancing the dry etching and is set low during forming the protective film.

9. A method for etching a silicon substrate according to claim 5, wherein a reactive gas is used for said etching gas.

10. A method for etching a silicon substrate, comprising repeating in sequence:
forming an etching mask on a silicon substrate surface; and
performing an etching step for forming a predetermined structured surface by dry etching said silicon substrate surface through an opening in said etching mask using an etching gas converted to plasma via high-frequency electrical power,
wherein said etching step comprises repeatedly performing in sequence:
providing a bias voltage by continuously applying electrical power to said silicon substrate during said etching step,
advancing primarily dry etching of an etching ground using an etching gas and a protective film forming gas; and
forming a protective film primarily on a structured surface perpendicular to said etching ground using an etching gas and a protective film forming gas.

11. A method for etching a silicon substrate according to claim 10, wherein a small amount of said protective film forming gas is supplied during advancing the dry etching and a large amount of said protective film forming gas is supplied in forming the protective film.

12. A method for etching a silicon substrate according to claim 10, wherein electrical power applied to said silicon substrate is set high during advancing the dry etching and is set low during forming the protective film.

13. A method for etching a silicon substrate according to claim 10, wherein a reactive gas is used for said etching gas.

14. A method for etching a silicon substrate according to claim 13, wherein an etching gas and a protective film forming gas converted to plasma are used; and said high-frequency electrical power used when generating plasma is set high during advancing the dry etching and set low during forming the protective film.

15. A device for etching a silicon substrate comprising:
an etching chamber for housing a silicon substrate serving as an item to be etched;
a base disposed below said etching chamber and on which said silicon substrate is mounted;
means for supplying an etching gas to said etching chamber;
means for supplying a protective film forming gas to said etching chamber;
means for reducing pressure in said etching chamber;
means for generating plasma, including a coil disposed at an outer perimeter of said etching chamber and opposing said etching chamber, wherein high-frequency electrical power is applied to said coil, and the etching gas and the protective film forming gas supplied to said etching chamber are converted to plasma;
means for applying high-frequency electrical base power to said base;
means for controlling gas flow of said etching gas and said protective film forming gas supplied to said etching chamber by said etching gas supplying means and said protective film forming gas supplying means;
means for controlling electrical coil power applied to said coil in said plasma generating means; and
means for controlling electrical power applied to said base by said high-frequency electrical base power applying means;
wherein said gas flow controlling means is formed so that said protective film forming gas is continuously supplied to said etching chamber and said etching gas is intermittently supplied to said etching gas.

16. A device for etching a silicon substrate according to claim 15, wherein said gas flow controlling means supplies a large amount of said protective film forming gas to said etching chamber when said etching gas is not being supplied and a small amount of said protective film forming gas to said etching chamber when said etching gas is being supplied.

17. A device for etching a silicon substrate according to claim 15, wherein said electrical base power controlling means periodically changes said electrical power applied to said base, applying low electrical power to said base when said etching gas is not being supplied and applying high electrical power when said etching gas is being supplied.

18. A device for etching a silicon substrate according to claim 15, wherein said electrical coil power controlling means periodically changes power applied to said coil, applying low electrical power when said etching gas is not being supplied and applying high electrical power when said etching gas is being supplied.

19. A device for etching etching a silicon substrate comprising:
an etching chamber for housing a silicon substrate serving as an item to be etched;
a base disposed below said etching chamber and on which said silicon substrate is mounted
means for supplying an etching gas to said etching chamber;
means for supplying a protective film forming gas to said etching chamber;
means for reducing pressure in said etching chamber;
means for generating plasma, including a coil disposed at an outer perimeter of said etching chamber and opposing said etching chamber, wherein high-frequency electrical power is applied to said coil, and the etching gas and the protective film forming gas supplied to said etching chamber are converted to plasma;
means for applying high-frequency electrical base power to said base;
means for controlling gas flow of said etching gas and said protective film forming gas supplied to said etching chamber by said etching gas supplying means and said protective film forming gas supplying means;
means for controlling electrical coil power applied to said coil in said plasma generating means; and
means for controlling electrical power applied to said base by said high-frequency electrical base power applying means;
wherein said gas flow controlling means is formed so that said etching gas and said protective film forming gas are continuously supplied to said etching chamber while flows thereof are periodically changed, with said flows being controlled so that phases thereof are opposite of each other.

20. A device for etching a silicon substrate according to claim 19, wherein said electrical base power controlling means periodically changes electrical power applied to said base, applying low electrical power when a small amount of said etching gas is being supplied and applying high electrical power to said base when a large amount of said etching gas is being supplied.

21. An device for etching a silicon substrate according to claim 19, wherein said electrical coil power controlling means periodically changes electrical power applied to said coil, applying low electrical power when a small amount of said etching gas is being supplied and applying a high electrical power when a large amount of said etching gas is being supplied.

22. A device for etching a silicon substrate comprising:
an etching chamber for housing a silicon substrate serving as an item to be etched;
a base disposed below said etching chamber and on which said silicon substrate is mounted;
means for supplying an etching gas to said etching chamber;
means for supplying a protective film forming gas in said etching chamber;
means for reducing pressure in said etching chamber;
means for generating plasma, including a coil disposed at an outer perimeter of said etching chamber and opposing said etching chamber, wherein high-frequency electrical power is applied to said coil, and the etching gas and the protective film forming gas supplied to said etching chamber are converted to plasma;
means for applying high-frequency electrical base power to said base;
means for controlling gas flow of said etching gas and said protective film forming gas supplied to said etching chamber by said etching gas supplying means and said protective film forming gas supplying means;
means for controlling electrical coil power applied to said coil in said plasma generating means; and
means for controlling electrical base power applied to said base by said high-frequency electrical base power applying means;
wherein said electrical base power controlling means is formed so that said electrical power applied to said base is periodically changed.

23. A device for etching a silicon substrate according to claim 22, wherein said means for controlling electrical coil power periodically changes said electrical power applied to said coil.

24. A device for etching a silicon substrate comprising:
an etching chamber for housing a silicon substrate serving as an item to be etched;
a base disposed below said etching chamber and on which said silicon substrate is mounted;
means for supplying an etching gas in said etching chamber;
means for supplying a protective film forming gas in said etching chamber;
means for reducing pressure in said etching chamber;
means for generating plasma, including a coil disposed at an outer perimeter of said etching chamber and opposing said etching chamber, wherein high-frequency electrical power is applied to said coil, and the etching gas and the protective film forming gas supplied to said etching chamber are converted to plasma;
means for applying high-frequency electrical base power to said base;
means for controlling gas flow of said etching gas and said protective film forming gas supplied to said etching chamber by said etching gas supplying means and said protective film forming gas supplying means;
means for controlling electrical coil power applied to said coil in said plasma generating means; and
means for controlling electrical base power applied to said base by said high-frequency electrical base power applying means;
wherein said electrical coil power controlling means is formed so that electrical power applied to said coil is periodically changed.
